(19) United States
(12) Patent Application Publication
(10) Pub. No.: US 2023/0153318 A1
(43) Pub. Date: May 18, 2023

(54) SHAPE AND DATA FORMAT CONVERSION FOR ACCELERATORS

(71) Applicant: INTERNATIONAL BUSINESS MACHINES CORPORATION, Armonk, NY (US)

(72) Inventors: YASUSHI NEGISHI, Machida-shi (JP); Tung D. Le, Ichikawa (JP); HARUKI IMAI, Yokohama-shi (JP); KIYOKUNI KAWACHIYA, Yokohama (JP)

(21) Appl. No.: 17/527,545

(22) Filed: Nov. 16, 2021

(51) Int. Cl. G06F 16/25; G06N 3/08; G06F 16/23

(52) U.S. Cl. CPC G06F 16/258; G06F 16/2365; G06N 3/08

(57) ABSTRACT

A method for converting a shape and a format of tensor data to meet a specific data format of a hardware accelerator is provided. The method receives input tensors L₁ and L₂, each being constants having a data format of < X x Y x Z >, and each further having an n-dimension input tensor shape as <Xₙ x Xₙ₋₁ x Xₙ₋₂ x ... x X₁ >. The method stores input tensor shape. The method calculates an n-dimension modified shape of the input tensors by (a) setting a largest divisor of (Xₙ x Xₙ₋₁ x...x X₁ ) ≤ L₁ to S₁, (b) setting a largest divisor of ((Xₙ x Xₙ₋₁ x...x X₁ ) / S₁) ≤ L₂ to S₂, (c) setting (((Xₙ x Xₙ₋₁ x... x X₁ ) / (S₁ x S₂)) to S₃, and (d) returning the n-dimension modified shape as < S₃ x S₂ x S₁ >.

### BACKGROUND

The present invention generally relates to hardware accelerators, and more particularly to a shape and data format conversion for accelerators.

Deep learning processing is executed by Central Processing Units (CPUs) and accelerators in general. Many accelerators require specific data formats, so that format conversions are required to use accelerators. Conventional format conversion techniques can result in increased converted data size and/or require a redundant buffer especially with effects of alignment required for accelerators. Accordingly, there is a need for an improved format conversion technique for accelerators.

### SUMMARY

According to aspects of the present invention, a computer-implemented method for converting a shape and a format of tensor data to meet a specific data format of a hardware accelerator is provided. The method includes receiving input tensors L₁ and L₂, each being constants having a data format of < X x Y x Z >, and each further having an n-dimension input tensor shape as <Xₙ × Xₙ₋₁ × Xₙ₋₂ × ... × X₁>. The method further includes storing the n-dimension input tensor shape of the input tensors L₁ and L₂. The method also includes calculating an n-dimension modified shape of the input tensors L₁ and L₂ by (a) setting a largest divisor of (Xₙ × Xₙ₋₁ ×...× X₁) that is less or equal to L₁ to S₁, (b) setting a largest divisor of ((Xₙ × Xₙ₋₁ ×...× X₁) / S₁) that is less or equal to L₂ to S₂, (c) setting (((Xₙ × Xₙ₋₁ ×... × X₁) / (S₁ × S₂)) to S₃, and (d) returning the n-dimension modified shape as < S₃ x S₂ x S₁ >. The method additionally includes changing the n-dimension input tensor shape of the input tensors L₁ and L₂ to the n-dimension modified shape to obtain shape modified input tensors. The method further includes converting a data format of the shape modified input tensors from <X x Y x Z> to < X x (Y ceildiv D) x (Z ceildiv D) x D x D >) to obtain format and shape converted input tensors having the specific data format of the hardware accelerator, where D is a constant value of a last dimension Z of the input tensors L₁ and L₂. The method also includes executing, by the hardware accelerator, target operations on the format and shape converted input tensors to obtain result tensors.

According to other aspects of the present invention, a computer program product for converting a shape and a format of tensor data to meet a specific data format of a hardware accelerator is provided. The computer program product includes a non-transitory computer readable storage medium having program instructions embodied therewith. The program instructions are executable by a computer to cause the computer to perform a method. The method includes receiving, by a central processing unit (CPU), input tensors L₁ and L₂, each being constants having a data format of <X × Y × Z >, and each further having an n-dimension input tensor shape as <Xₙ × Xₙ₋₁ × Xₙ₋₂ × ... × X₁>. The method further includes storing, by the CPU, the n-dimension input tensor shape of the input tensors L₁ and L₂. The method also includes calculating, by the CPU, an n-dimension modified shape of the input tensors L₁ and L₂ by (a) setting a largest divisor of (Xₙ × Xₙ₋₁ ×...× X₁) that is less or equal to L₁ to S₁, (b) setting a largest divisor of ((Xₙ × Xₙ₋₁ ×...× X₁) / S₁) that is less or equal to L₂ to S₂, (c) setting (((Xₙ × Xₙ₋₁ ×... × X₁) / (S₁ × S₂)) to S₃, and (d) returning the n-dimension modified shape as <S₃ × S₂ × S₁>. The method additionally includes changing, by the CPU, the n-dimension input tensor shape of the input tensors L₁ and L₂ to the n-dimension modified shape to obtain shape modified input tensors. The method further includes converting, by the CPU, a data format of the shape modified input tensors from <X x Y x Z> to < X x (Y ceildiv D) x (Z ceildiv D) x D x D >) to obtain format and shape converted input tensors having the specific data format of the hardware accelerator, where D is a constant value of a last dimension Z of the input tensors L₁ and L₂. The method also includes executing, by the hardware accelerator, target operations on the format and shape converted input tensors to obtain result tensors.

According to yet other aspects of the present invention, a computer processing system for converting a shape and a format of tensor data to meet a specific data format of a hardware accelerator is provided. The computer processing system includes a memory device for storing program code. The computer processing system further includes a central processing unit (CPU) operatively coupled to the memory device for running the program code to receive input tensors L₁ and L₂, each being constants having a data format of < X × Y × Z >, and each further having an n-dimension input tensor shape as <Xₙ × Xₙ₋₁ × Xₙ₋₂ × ... × X₁>. The CPU further runs the program code to store the n-dimension input tensor shape of the input tensors L₁ and L₂. The CPU also runs the program code to calculate an n-dimension modified shape of the input tensors L₁ and L₂ by (a) setting a largest divisor of (Xₙ × Xₙ₋₁ ×...× X₁) that is less or equal to L₁ to S₁, (b) setting a largest divisor of ((Xₙ × Xₙ₋₁ ×...× X₁) / S₁) that is less or equal to L₂ to S₂, (c) setting (((Xₙ × Xₙ₋₁ ×... × X₁) / (S₁ × S₂)) to S₃, and (d) returning the n-dimension modified shape as < S₃ × S₂ × S₁ >. The CPU additionally runs the program code to change the n-dimension input tensor shape of the input tensors L₁ and L₂ to the n-dimension modified shape to obtain shape modified input tensors. The CPU further runs the program code to convert a data format of the shape modified input tensors from <X × Y × Z> to < X × (Y ceildiv D) × (Z ceildiv D) × D × D >) to obtain format and shape converted input tensors having the specific data format of the hardware accelerator, where D is a constant value of a last dimension Z of the input tensors L₁ and L₂. A hardware accelerator operatively coupled to the memory device and the CPU executes target operations on the format and shape converted input tensors to obtain result tensors.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a block diagram showing an exemplary computing device, in accordance with an embodiment of the present invention;

FIG. 2 is a flow diagram showing an exemplary system for converting a shape and a format of tensor data to meet a specific data format of a hardware accelerator, in accordance with an embodiment of the present invention;

FIG. 3 is a flow diagram showing an exemplary method for converting a shape and a format of tensor data to meet a specific data format of a central processing unit after computations have been performed on the tensor data by a hardware accelerator, in accordance with an embodiment of the present invention;

FIG. 4 is a flow diagram showing an exemplary method for executing element-wise operations by a hardware accelerator, in accordance with an embodiment of the present invention;

FIG. 5 is a block diagram showing another exemplary computing device, in accordance with an embodiment of the present invention;

FIG. 6 is a block diagram showing an illustrative cloud computing environment having one or more cloud computing nodes with which local computing devices used by cloud consumers communicate, in accordance with an embodiment of the present invention; and

FIG. 7 is a block diagram showing a set of functional abstraction layers provided by a cloud computing environment, in accordance with an embodiment of the present invention.

### DETAILED DESCRIPTION

Embodiments of the present invention are directed to a shape and data format conversion for accelerators.

Embodiments of the present invention allow for data that cannot be processed by an accelerator due to incompatible format to be suitable converted for use by the accelerator, because most accelerators have conditions for data formats. For example, they have maximum data sizes for data elements (e.g. 64 KB), and each element unit should start with aligned addresses (e.g. 64 B aligned). Embodiments of the present invention can re-convert the data back to a format that is compatible with a central processing unit.

Embodiments of the present invention allow for such data conversation for accelerator processor withing increasing an amount of data or requiring a redundant buffer as per conventional approaches. Embodiments of the present invention enable a hardware accelerator, having optimizing processing in certain respects over a CPU, to be able to more efficiently process data than a CPU after a conversion to a suitable data shape and format for the hardware accelerator. In this way, the quicker processing of the hardware accelerator can be exploited to improve the overall functioning of the computer.

As used herein, the term “data shape” refers to a logical shape of a tensor for compilers of N dimensional matrix data, including sizes of all dimensions of the matrix. The term “data shape” is used for both an original tensor and a tensor converted for accelerators.

Moreover, the term “data format” refers to an actual memory layout of the tensor in memory space. The data format for a tensor converted for accelerators should meet the accelerator conditions.

According to embodiments of the present invention, a compiler chooses a minimum data shape for accelerators. The main target operations are element-wise operations, because results are not affected by the shape, and the compiler can choose a best data shape to minimize the memory size.

In an embodiment, the present invention can involve the following steps:
(1) Change the input shape to be suitable for the supported data conversion;
(2) Convert the input tensor format for processing by an accelerator;
(3) Execute operations by the accelerator;
(4) Convert the result tensor format for processing by a CPU; and
(5) Restore the adequate shape for the result tensors for processing by the CPU.

In an embodiment, tensors can be processed by a hardware accelerator, and then the results of the processing can be presented by a central processing unit. Data incompatibilities between the two types of processing units are addressed by present invention.

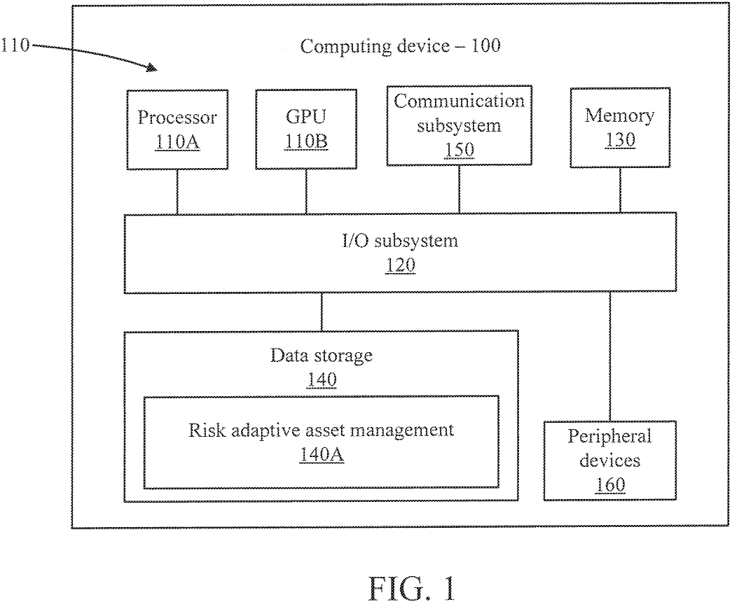

FIG. 1 is a block diagram showing an exemplary computing device 100, in accordance with an embodiment of the present invention. The computing device 100 is configured to perform shape and data format conversion for a hardware accelerator.

The computing device 100 may be embodied as any type of computation or computer device capable of performing the functions described herein, including, without limitation, a computer, a server, a rack based server, a blade server, a workstation, a desktop computer, a laptop computer, a notebook computer, a tablet computer, a mobile computing device, a wearable computing device, a network appliance, a web appliance, a distributed computing system, a processor- based system, and/or a consumer electronic device. Additionally or alternatively, the computing device 100 may be embodied as a one or more compute sleds, memory sleds, or other racks, sleds, computing chassis, or other components of a physically disaggregated computing device. As shown in FIG. 1, the computing device 100 illustratively includes the processor 110, an input/output subsystem 120, a memory 130, a data storage device 140, and a communication subsystem 150, and/or other components and devices commonly found in a server or similar computing device. Of course, the computing device 100 may include other or additional components, such as those commonly found in a server computer (e.g., various input/output devices), in other embodiments. Additionally, in some embodiments, one or more of the illustrative components may be incorporated in, or otherwise form a portion of, another component. For example, the memory 130, or portions thereof, may be incorporated in the processor 110 in some embodiments.

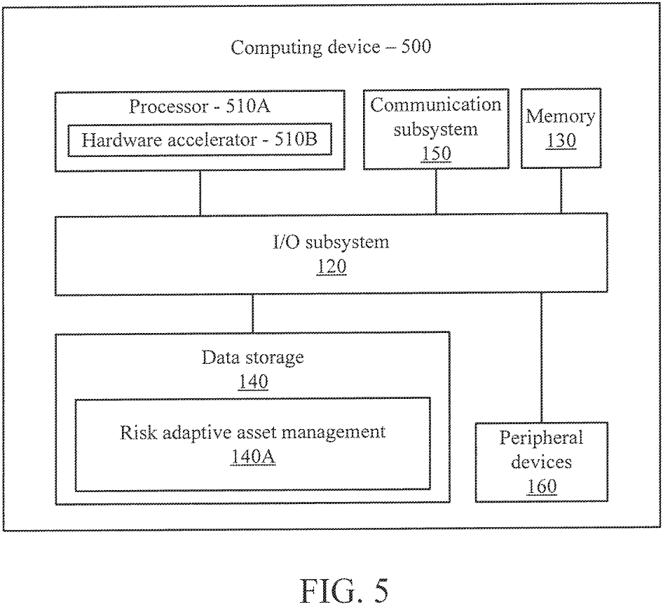

The processor 110 may be embodied as any type of processor capable of performing the functions described herein. The processor 110 may be embodied as a single processor, multiple processors, a Central Processing Unit(s) (CPU(s)), a Graphics Processing Unit(s) (GPU(s)), a single or multi-core processor(s), a digital signal processor(s), a microcontroller(s), or other processor(s) or processing/controlling circuit(s). In an embodiment, the processor 110 is implemented as a CPU 110A and a separate GPU 110B, as shown for the sake of illustration. In another embodiment, the processor 110 is implemented as a CPU with a hardware accelerator portion (see FIG. 5). In another embodiment, the processor 110 is implemented as a CPU and a tensor processing unit, the latter serving as a hardware accelerator (see also FIG. 5). These and other variations of processor 110 to which the present invention can be applied are readily contemplated by one of ordinary skill in the art given the teachings of the present invention provided herein.

The memory 130 may be embodied as any type of volatile or non-volatile memory or data storage capable of performing the functions described herein. In operation, the memory 130 may store various data and software used during operation of the computing device 100, such as operating systems, applications, programs, libraries, and drivers. The memory 130 is communicatively coupled to the processor 110 via the I/O subsystem 120, which may be embodied as circuitry and/or components to facilitate input/output operations with the processor 110 the memory 130, and other components of the computing device 100. For example, the I/O subsystem 120 may be embodied as, or otherwise include, memory controller hubs, input/output control hubs, platform controller hubs, integrated control circuitry, firmware devices, communication links (e.g., point-to-point links, bus links, wires, cables, light guides, printed circuit board traces, etc.) and/or other components and subsystems to facilitate the input/output operations. In some embodiments, the I/O subsystem 120 may form a portion of a system-on-a-chip (SOC) and be incorporated, along with the processor 110, the memory 130, and other components of the computing device 100, on a single integrated circuit chip.

The data storage device 140 may be embodied as any type of device or devices configured for short-term or long-term storage of data such as, for example, memory devices and circuits, memory cards, hard disk drives, solid state drives, or other data storage devices. The data storage device 140 can store program code for shape and data format conversion for a hardware accelerator. The communication subsystem 150 of the computing device 100 may be embodied as any network interface controller or other communication circuit, device, or collection thereof, capable of enabling communications between the computing device 100 and other remote devices over a network. The communication subsystem 150 may be configured to use any one or more communication technology (e.g., wired or wireless communications) and associated protocols (e.g., Ethernet, InfiniBand®, Bluetooth®, Wi-Fi®, WiMAX, etc.) to effect such communication.

As shown, the computing device 100 may also include one or more peripheral devices 160. The peripheral devices 160 may include any number of additional input/output devices, interface devices, and/or other peripheral devices. For example, in some embodiments, the peripheral devices 160 may include a display, touch screen, graphics circuitry, keyboard, mouse, speaker system, microphone, network interface, and/or other input/output devices, interface devices, and/or peripheral devices.

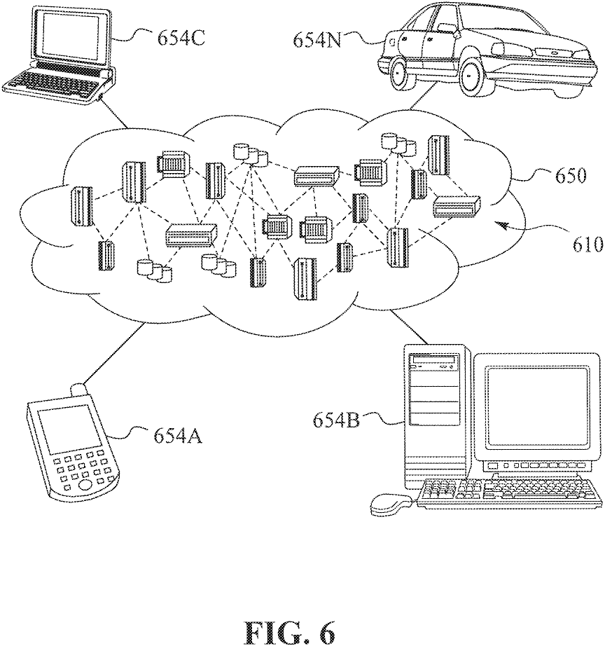

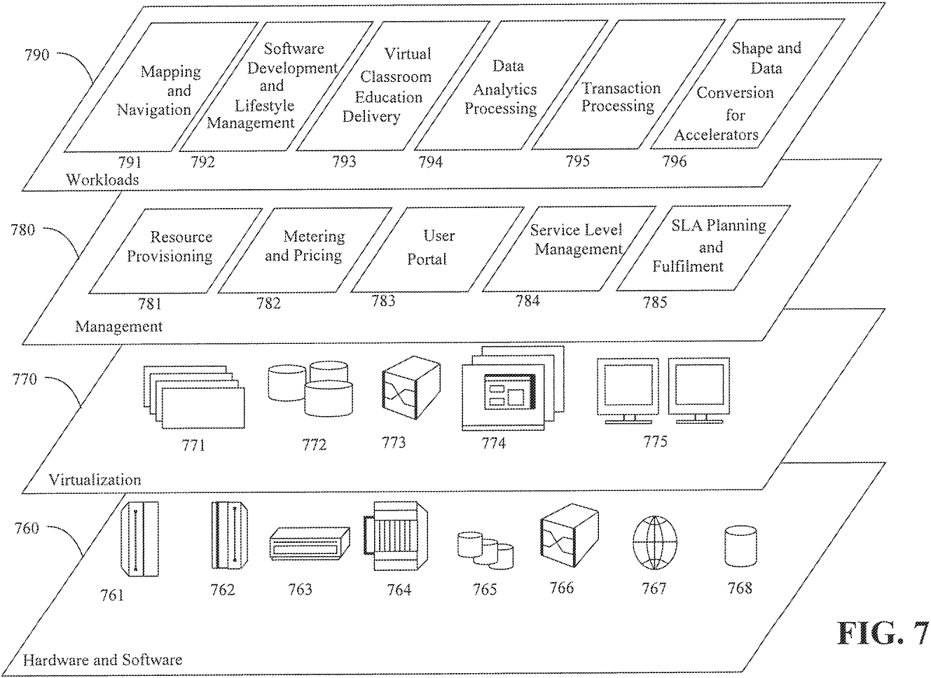

Of course, the computing device 100 may also include other elements (not shown), as readily contemplated by one of skill in the art, as well as omit certain elements. For example, various other input devices and/or output devices can be included in computing device 100, depending upon the particular implementation of the same, as readily understood by one of ordinary skill in the art. For example, various types of wireless and/or wired input and/or output devices can be used. Moreover, additional processors, controllers, memories, and so forth, in various configurations can also be utilized. Further, in another embodiment, a cloud configuration can be used (e.g., see FIGS. 6-7). For example, processing can be performed in the cloud using the technique of the present invention and a configuration as described with respect to FIGS. 6-7. These and other variations of the processing system 100 are readily contemplated by one of ordinary skill in the art given the teachings of the present invention provided herein.

As employed herein, the term “hardware processor subsystem” or “hardware processor” can refer to a processor, memory (including RAM, cache(s), and so forth), software (including memory management software) or combinations thereof that cooperate to perform one or more specific tasks. In useful embodiments, the hardware processor subsystem can include one or more data processing elements (e.g., logic circuits, processing circuits, instruction execution devices, etc.). The one or more data processing elements can be included in a central processing unit, a graphics processing unit, and/or a separate processor- or computing element-based controller (e.g., logic gates, etc.). The hardware processor subsystem can include one or more on-board memories (e.g., caches, dedicated memory arrays, read only memory, etc.). In some embodiments, the hardware processor subsystem can include one or more memories that can be on or off board or that can be dedicated for use by the hardware processor subsystem (e.g., ROM, RAM, basic input/output system (BIOS), etc.).

In some embodiments, the hardware processor subsystem can include and execute one or more software elements. The one or more software elements can include an operating system and/or one or more applications and/or specific code to achieve a specified result.

In other embodiments, the hardware processor subsystem can include dedicated, specialized circuitry that performs one or more electronic processing functions to achieve a specified result. Such circuitry can include one or more application-specific integrated circuits (ASICs), FPGAs, and/or PLAs.

These and other variations of a hardware processor subsystem are also contemplated in accordance with embodiments of the present invention

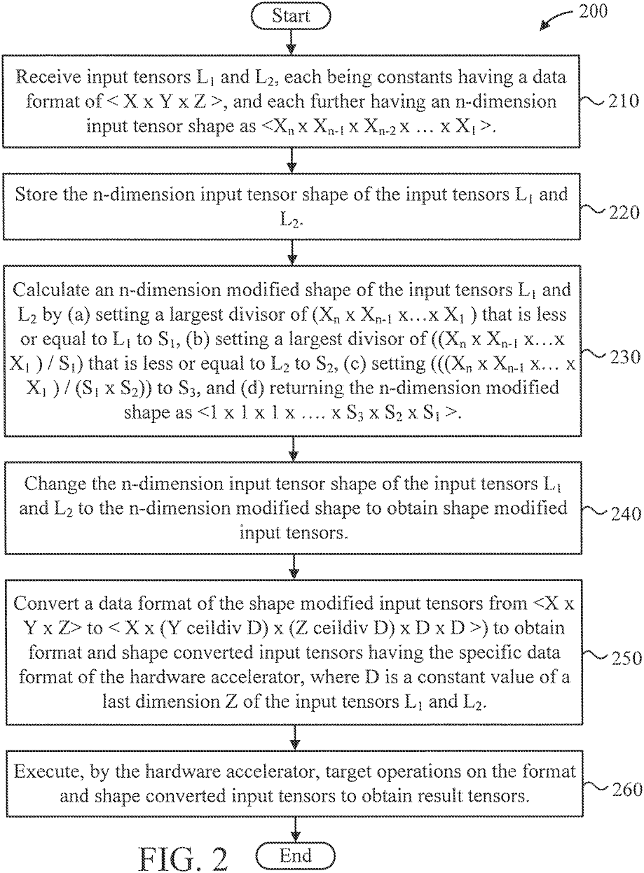

FIG. 2 is a flow diagram showing an exemplary system 200 for converting a shape and a format of tensor data to meet a specific data format of a hardware accelerator, in accordance with an embodiment of the present invention.

At block 210, receive input tensors L₁ and L₂, each being constants having a data format of < X × Y × Z >, and each further having an n-dimension input tensor shape as <Xₙ × Xₙ₋₁ × Xₙ₋₂ × ... × X₁>.

At block 220, store the n-dimension input tensor shape of the input tensors L₁ and L₂.

At block 230, calculate an n-dimension modified shape of the input tensors L₁ and L₂ by (a) setting a largest divisor of (Xₙ × Xₙ₋₁ ×...× X₁) that is less or equal to L₁ to S₁, (b) setting a largest divisor of ((Xₙ × Xₙ₋₁ ×...× X₁) / S₁) that is less or equal to L₂ to S₂, (c) setting (((Xₙ × Xₙ₋₁ ×... × X₁) / (S₁ × S₂)) to S₃, and (d) returning the n-dimension modified shape as <S₃ × S₂ × S₁>.

At block 240, change the n-dimension input tensor shape of the input tensors L₁ and L₂ to the n-dimension modified shape to obtain shape modified input tensors.

At block 250, convert a data format of the shape modified input tensors from <X x Y x Z> to < X × (Y ceildiv D) × (Z ceildiv D) × D × D >) to obtain format and shape converted input tensors having the specific data format of the hardware accelerator, where D is a constant value of a last dimension Z of the input tensors L₁ and L₂.

At block 260, execute, by the hardware accelerator, target operations on the format and shape converted input tensors to obtain result tensors.

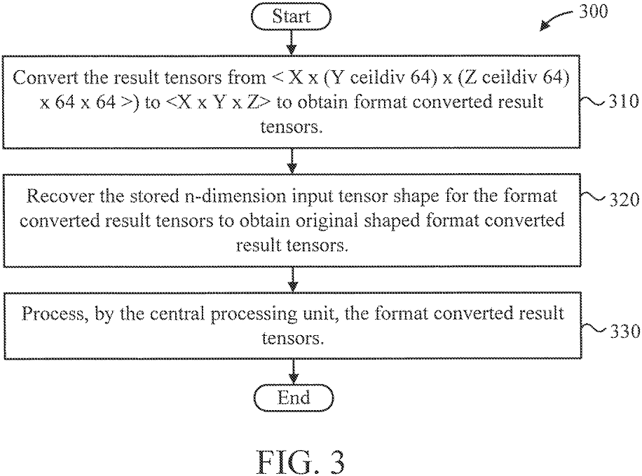

FIG. 3 is a flow diagram showing an exemplary method 300 for converting a shape and a format of tensor data to meet a specific data format of a central processing unit after computations have been performed on the tensor data by a hardware accelerator, in accordance with an embodiment of the present invention.

At block 310, convert the result tensors from < X × (Y ceildiv 64) × (Z ceildiv 64) × 64 × 64 >) to <X × Y × Z> to obtain format converted result tensors. In an embodiment, the format converted result tensors have a format compatible with a central processing unit and incompatible with the hardware accelerator. While 64 is used as the constant size of the arrays, other values can be substituted depending on the limits of the hardware accelerator.

At block 320, recover the stored n-dimension input tensor shape for the format converted result tensors to obtain original shaped format converted result tensors.

At block 330, process, by the central processing unit, the format converted result tensors.

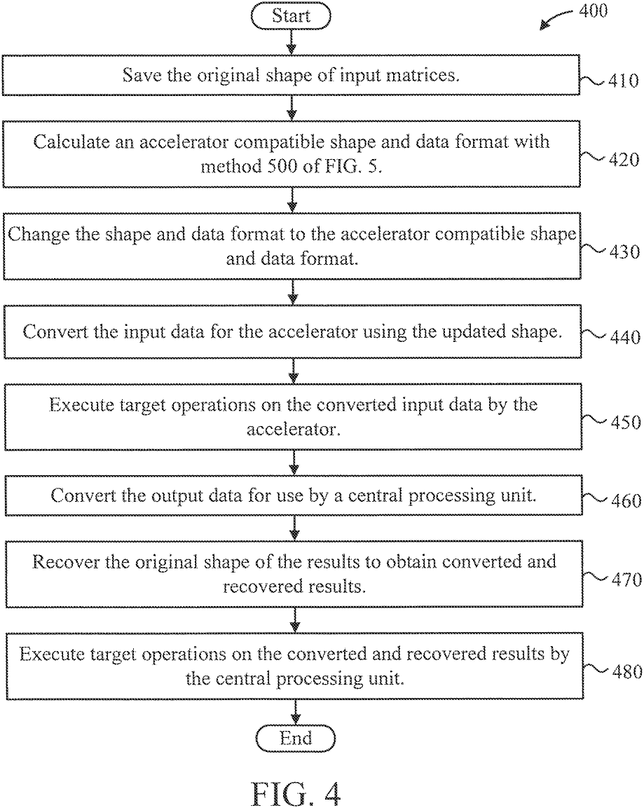

FIG. 4 is a flow diagram showing an exemplary method 400 for executing element-wise operations by a hardware accelerator, in accordance with an embodiment of the present invention.

At block 410, save the original shape of input matrices.

At block 420, calculate an accelerator compatible shape and data format with method 500 of FIG. 5. An accelerator compatible shape and data format refer to a data shape and data format that is compatible with a hardware accelerator, but not necessarily compatible with a central processing unit.

At block 430, change the shape and data format to the accelerator compatible shape and data format.

At block 440, convert the input data for the accelerator using the updated shape.

At block 450, execute target operations on the converted input data by the accelerator.

At block 460, convert the output data for use by a central processing unit.

At block 470, recover the original shape of the results to obtain converted and recovered results.

At block 480, execute target operations on the converted and recovered results by the central processing unit.

FIG. 5 is a block diagram showing another exemplary computing device 500, in accordance with an embodiment of the present invention.

Computing device 500 differs from computing device 100 in having a combined CPU and hardware accelerator. That is, the CPU 510A includes a hardware accelerator 510B. The hardware accelerator 510B can be a tensor processing unit.

It is to be understood that although this disclosure includes a detailed description on cloud computing, implementation of the teachings recited herein are not limited to a cloud computing environment. Rather, embodiments of the present invention are capable of being implemented in conjunction with any other type of computing environment now known or later developed.

Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service. This cloud model may include at least five characteristics, at least three service models, and at least four deployment models.

Characteristics are as follows:
On-demand self-service: a cloud consumer can unilaterally provision computing capabilities, such as server time and network storage, as needed automatically without requiring human interaction with the service’s provider.
Broad network access: capabilities are available over a network and accessed through standard mechanisms that promote use by heterogeneous thin or thick client platforms (e.g., mobile phones, laptops, and PDAs).
Resource pooling: the provider’s computing resources are pooled to serve multiple consumers using a multi-tenant model, with different physical and virtual resources dynamically assigned and reassigned according to demand. There is a sense of location independence in that the consumer generally has no control or knowledge over the exact location of the provided resources but may be able to specify location at a higher level of abstraction (e.g., country, state, or datacenter).
Rapid elasticity: capabilities can be rapidly and elastically provisioned, in some cases automatically, to quickly scale out and rapidly released to quickly scale in. To the consumer, the capabilities available for provisioning often appear to be unlimited and can be purchased in any quantity at any time.
Measured service: cloud systems automatically control and optimize resource use by leveraging a metering capability at some level of abstraction appropriate to the type of service (e.g., storage, processing, bandwidth, and active user accounts). Resource usage can be monitored, controlled, and reported, providing transparency for both the provider and consumer of the utilized service.

Service Models are as follows:
Software as a Service (SaaS): the capability provided to the consumer is to use the provider’s applications running on a cloud infrastructure. The applications are accessible from various client devices through a thin client interface such as a web browser (e.g., web-based e-mail). The consumer does not manage or control the underlying cloud infrastructure including network, servers, operating systems, storage, or even individual application capabilities, with the possible exception of limited user-specific application configuration settings.
Platform as a Service (PaaS): the capability provided to the consumer is to deploy onto the cloud infrastructure consumer-created or acquired applications created using programming languages and tools supported by the provider. The consumer does not manage or control the underlying cloud infrastructure including networks, servers, operating systems, or storage, but has control over the deployed applications and possibly application hosting environment configurations.
Infrastructure as a Service (IaaS): the capability provided to the consumer is to provision processing, storage, networks, and other fundamental computing resources where the consumer is able to deploy and run arbitrary software, which can include operating systems and applications. The consumer does not manage or control the underlying cloud infrastructure but has control over operating systems, storage, deployed applications, and possibly limited control of select networking components (e.g., host firewalls).

Deployment Models are as follows:
Private cloud: the cloud infrastructure is operated solely for an organization. It may be managed by the organization or a third party and may exist on-premises or off-premises.
Community cloud: the cloud infrastructure is shared by several organizations and supports a specific community that has shared concerns (e.g., mission, security requirements, policy, and compliance considerations). It may be managed by the organizations or a third party and may exist on-premises or off-premises.
Public cloud: the cloud infrastructure is made available to the general public or a large industry group and is owned by an organization selling cloud services.
Hybrid cloud: the cloud infrastructure is a composition of two or more clouds (private, community, or public) that remain unique entities but are bound together by standardized or proprietary technology that enables data and application portability (e.g., cloud bursting for load-balancing between clouds).

A cloud computing environment is service oriented with a focus on statelessness, low coupling, modularity, and semantic interoperability. At the heart of cloud computing is an infrastructure that includes a network of interconnected nodes.

Referring now to FIG. 6, illustrative cloud computing environment 650 is depicted. As shown, cloud computing environment 650 includes one or more cloud computing nodes 610 with which local computing devices used by cloud consumers, such as, for example, personal digital assistant (PDA) or cellular telephone 654A, desktop computer 654B, laptop computer 654C, and/or automobile computer system 654N may communicate. Nodes 610 may communicate with one another. They may be grouped (not shown) physically or virtually, in one or more networks, such as Private, Community, Public, or Hybrid clouds as described hereinabove, or a combination thereof. This allows cloud computing environment 650 to offer infrastructure, platforms and/or software as services for which a cloud consumer does not need to maintain resources on a local computing device. It is understood that the types of computing devices 654A-N shown in FIG. 6 are intended to be illustrative only and that computing nodes 610 and cloud computing environment 650 can communicate with any type of computerized device over any type of network and/or network addressable connection (e.g., using a web browser).

Referring now to FIG. 7, a set of functional abstraction layers provided by cloud computing environment 650 (FIG. 6) is shown. It should be understood in advance that the components, layers, and functions shown in FIG. 7 are intended to be illustrative only and embodiments of the invention are not limited thereto. As depicted, the following layers and corresponding functions are provided:

Hardware and software layer 760 includes hardware and software components. Examples of hardware components include: mainframes 761; RISC (Reduced Instruction Set Computer) architecture based servers 762; servers 763; blade servers 764; storage devices 765; and networks and networking components 766. In some embodiments, software components include network application server software 767 and database software 768.

Virtualization layer 770 provides an abstraction layer from which the following examples of virtual entities may be provided: virtual servers 771; virtual storage 772; virtual networks 773, including virtual private networks; virtual applications and operating systems 774; and virtual clients 775.

In one example, management layer 780 may provide the functions described below. Resource provisioning 781 provides dynamic procurement of computing resources and other resources that are utilized to perform tasks within the cloud computing environment. Metering and Pricing 782 provide cost tracking as resources are utilized within the cloud computing environment, and billing or invoicing for consumption of these resources. In one example, these resources may include application software licenses. Security provides identity verification for cloud consumers and tasks, as well as protection for data and other resources. User portal 783 provides access to the cloud computing environment for consumers and system administrators. Service level management 784 provides cloud computing resource allocation and management such that required service levels are met. Service Level Agreement (SLA) planning and fulfillment 785 provide pre-arrangement for, and procurement of, cloud computing resources for which a future requirement is anticipated in accordance with an SLA.

Workloads layer 790 provides examples of functionality for which the cloud computing environment may be utilized. Examples of workloads and functions which may be provided from this layer include: mapping and navigation 791; software development and lifecycle management 792; virtual classroom education delivery 793; data analytics processing 794; transaction processing 795; and shape and data format conversion for accelerators 796.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as SMALLTALK, C++ or the like, and conventional procedural programming languages, such as the “C” programming language or similar programming languages. The computer readable program instructions may execute entirely on the user’s computer, partly on the user’s computer, as a stand-alone software package, partly on the user’s computer and partly on a remote computer or entirely on the remote computer or server. In the latter scenario, the remote computer may be connected to the user’s computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as readily apparent by one of ordinary skill in this and related arts, for as many items listed.

Having described preferred embodiments of a system and method (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A computer-implemented method for converting a shape and a format of tensor data to meet a specific data format of a hardware accelerator, comprising:
receiving input tensors L₁ and L₂, each being constants having a data format of < X x Y x Z >, and each further having an n-dimension input tensor shape as <Xₙ x Xₙ₋₁ x Xₙ₋₂ x ... x X₁ >;
storing the n-dimension input tensor shape of the input tensors L₁ and L₂;
calculating an n-dimension modified shape of the input tensors L₁ and L₂ by (a) setting a largest divisor of (Xₙ x Xₙ₋₁ x...x X₁ ) that is less or equal to L₁ to S₁, (b) setting a largest divisor of ((Xₙ x Xₙ₋₁ x...x X₁ ) / S₁) that is less or equal to L₂ to S₂, (c) setting (((Xₙ x Xₙ₋₁ x... x X₁ ) / (S₁ x S₂)) to S₃, and (d) returning the n-dimension modified shape as < S₃ x S₂ x S₁ >;
changing the n-dimension input tensor shape of the input tensors L₁ and L₂ to the n-dimension modified shape to obtain shape modified input tensors;
converting a data format of the shape modified input tensors from <X x Y x Z> to < X x (Y ceildiv D) x (Z ceildiv D) x D x D >) to obtain format and shape converted input tensors having the specific data format of the hardware accelerator, where D is a constant value of a last dimension Z of the input tensors L₁ and L₂; and
executing, by the hardware accelerator, target operations on the format and shape converted input tensors to obtain result tensors.

2. The computer-implemented method of claim 1, further comprising:
converting the result tensors from < X x (Y ceildiv D) x (Z ceildiv D) x D x D >) to <X x Y x Z> to obtain format converted result tensors; and
recovering the stored n-dimension input tensor shape for the format converted result tensors to obtain original shaped format converted result tensors.

3. The computer-implemented method of claim 2, wherein the format converted result tensors have a format compatible with a central processing unit and incompatible with the hardware accelerator.

4. The computer-implemented method of claim 3, further comprising processing, by the central processing unit, the format converted result tensors.

5. The computer-implemented method of claim 1, wherein said converting steps convert the data format to have a same number of constituent elements.

6. The computer-implemented method of claim 1, wherein the hardware accelerator is a graphics processing unit.

7. The computer-implemented method of claim 1, wherein the hardware accelerator is comprised in a central processing unit.

8. The computer-implemented method of claim 1, wherein the hardware accelerator is a tensor processing unit.

9. The computer-implemented method of claim 1, wherein the last input tensor L₁ and the second to last input tensor L₂ is comprised in a sequence of tensors.

10. The computer-implemented method of claim 1, wherein a number of data elements in each of the input tensors and each of the result tensors are equal.

11. The computer-implemented method of claim 1, further comprising controlling a medical hardware device to perform a medical test on an organic sample provided by a human responsive to the original shaped converted result tensors.

12. The computer-implemented method of claim 1, wherein the hardware accelerator is constrained to only handle constant size arrays.

13. The computer-implemented method of claim 1, wherein the input tensor L₁ is a last input tensor and the input tensor L₂ is a second to last input tensor in a sequence of input tensors.

14. A computer program product for converting a shape and a format of tensor data to meet a specific data format of a hardware accelerator, the computer program product comprising a non-transitory computer readable storage medium having program instructions embodied therewith, the program instructions executable by a computer to cause the computer to perform a method comprising:
receiving, by a central processing unit (CPU), input tensors L₁ and L₂, each being constants having a data format of < X x Y x Z >, and each further having an n-dimension input tensor shape as <Xₙ x Xₙ₋₁ x Xₙ₋₂ x ... x X₁ >;
storing, by the CPU, the n-dimension input tensor shape of the input tensors L₁ and L₂;
calculating, by the CPU, an n-dimension modified shape of the input tensors L₁ and L₂ by (a) setting a largest divisor of (Xₙ x Xₙ₋₁ x...x X₁) that is less or equal to L₁ to S₁, (b) setting a largest divisor of ((Xₙ x Xₙ₋₁ x...x X₁ ) / S₁) that is less or equal to L₂ to S₂, (c) setting (((Xₙ x Xₙ₋₁ x... x X₁) / (S₁ x S₂)) to S₃, and (d) returning the n-dimension modified shape as < S₃ x S₂ x S₁ >;
changing, by the CPU, the n-dimension input tensor shape of the input tensors L₁ and L₂ to the n-dimension modified shape to obtain shape modified input tensors;
converting, by the CPU, a data format of the shape modified input tensors from <X x Y x Z> to < X x (Y ceildiv D) x (Z ceildiv D) x D x D >) to obtain format and shape converted input tensors having the specific data format of the hardware accelerator, where D is a constant value of a last dimension Z of the input tensors L₁ and L₂; and
executing, by the hardware accelerator, target operations on the format and shape converted input tensors to obtain result tensors.

15. The computer program product of claim 14, wherein the method further comprises:
converting the result tensors from < X x (Y ceildiv D) x (Z ceildiv D) x D x D >) to <X x Y x Z> to obtain format converted result tensors; and
recovering the stored n-dimension input tensor shape for the format converted result tensors to obtain original shaped format converted result tensors.

16. The computer program product of claim 15, wherein the format converted result tensors have a format compatible with a central processing unit and incompatible with the hardware accelerator.

17. The computer program product of claim 16, further comprising processing, by the central processing unit, the format converted result tensors.

18. The computer program product of claim 14, wherein said converting steps convert the data format to have a same number of constituent elements.

19. The computer program product of claim 14, wherein the hardware accelerator is a graphics processing unit.

20. A computer processing system for converting a shape and a format of tensor data to meet a specific data format of a hardware accelerator, comprising:
a memory device for storing program code;
a central processing unit operatively coupled to the memory device for running the program code to:
receive input tensors L₁ and L₂, each being constants having a data format of < X x Y x Z >, and each further having an n-dimension input tensor shape as <Xₙ x Xₙ₋₁ x Xₙ₋₂ x ... x X₁>;
store the n-dimension input tensor shape of the input tensors L₁ and L₂;
calculate an n-dimension modified shape of the input tensors L₁ and L₂ by (a) setting a largest divisor of (Xₙ x Xₙ₋₁ x...x X₁ ) that is less or equal to L₁ to S₁, (b) setting a largest divisor of ((Xₙ x Xₙ₋₁ x...x X₁ ) / S₁) that is less or equal to L₂ to S₂, (c) setting (((Xₙ x Xₙ₋₁ x... x X₁) / (S₁ x S₂)) to S₃, and (d) returning the n-dimension modified shape as < S₃ x S₂ x S₁ >;
change the n-dimension input tensor shape of the input tensors L₁ and L₂ to the n-dimension modified shape to obtain shape modified input tensors; and
convert a data format of the shape modified input tensors from <X x Y x Z> to < X x (Y ceildiv D) x (Z ceildiv D) x D x D >) to obtain format and shape converted input tensors having the specific data format of the hardware accelerator, where D is a constant value of a last dimension Z of the input tensors L₁ and L₂; and
a hardware accelerator operatively coupled to the memory device and the central processing unit for executing target operations on the format and shape converted input tensors to obtain result tensors.
